(19) United States
(12) Patent Application Publication
(10) Pub. No.: US 2009/0085157 A1
(43) Pub. Date: Apr. 2, 2009

(54) Manufacturing method for an integrated circuit, corresponding intermediate integrated circuit structure and corresponding integrated circuit

(76) Inventors: Klaus Muemmler, Dresden (DE); Stefan Tegen, Dresden (DE)

Correspondence Address: FAY KAPLUN & MARCIN, LLP, 150 BROADWAY, SUITE 702, NEW YORK, NY, 10038, US

(21) Appl. No.: 11/904,722

(22) Filed: Sep. 28, 2007

(51) Int. Cl. H01L 29/92; H01L 21/283

(52) U.S. Cl. 257/532; 438/386; 257/E21.159; 257/E29.342

(57) ABSTRACT

The present invention provides a method of manufacturing integrated circuit including a plurality of pillars, comprising the steps of: forming a plurality of first trenches in a first layer comprising a first material, thereby leaving a plurality of fins of the first material between said trenches; forming an infill comprising a second material in said first trenches; forming a plurality of second trenches in said first layer and said infill, the second trenches having sidewalls, walls, wherein first portions of said sidewalls expose the first material, and second portions of said sidewalls expose the second material; and removing either the first or the second material selectively to the respective other material, thereby leaving said pillars of the remaining material. The invention also provides a corresponding intermediate integrated circuit structure.

### BACKGROUND OF THE INVENTION

1. Field of the Invention

The present invention relates to a manufacturing method for an integrated circuit, a corresponding intermediate integrated circuit structure, and a corresponding integrated circuit.

2. Description of the Related Art

With feature sizes that are becoming smaller and smaller and nowadays are well below 100 nm, it becomes a challenging task to form integrated circuits having pillar elements with very small spatial extension, e.g. 1-4F², where F is the critical dimension of the used patterning technology. Forming appropriate mask openings for such pillar elements in a manner which is reliable and reproducible in mass production becomes more and more difficult.

### BRIEF SUMMARY OF THE INVENTION

Various aspects of the invention are listed in independent claims 1, 17, 20, and 28, respectively.

Further aspects are listed in the respective dependent claims.

### DESCRIPTION OF THE DRAWINGS

In the Figures:

FIG. 1A-E show schematic layouts for illustrating a manufacturing method of an integrated circuit in form of a capacitor array according to a first embodiment of the present invention, namely a) as plain view, b) as a cross-section along line A-A′ of a), and c) as a cross-section along line B-B′ of a);

FIG. 2A,B show schematic layouts for illustrating a manufacturing method of an integrated circuit in form of a capacitor array according to a second embodiment of the present invention, namely a) as plain view, b) as a cross-section along line A-A′ of a), and c) as a cross-section along line B-B′ of a);

FIG. 3 show schematic layouts for illustrating a manufacturing method of an integrated circuit in form of a capacitor array according to a third embodiment of the present invention, namely a) as plain view, b) as a cross-section along line A-A′ of a), and c) as a cross-section along line B-B′ of a);

FIG. 4A-D show schematic layouts for illustrating a manufacturing method of an integrated circuit in form of a capacitor array according to a fourth embodiment of the present invention, namely a) as plain view, b) as a cross-section along line A-A′ of a), and c) as a cross-section along line B-B′ of a);

FIG. 5A-D show schematic layouts for illustrating a manufacturing method of an integrated circuit in form of a capacitor array according to a fifth embodiment of the present invention, namely a) as plain view, b) as a cross-section along line A-A′ of a), and c) as a cross-section along line B-B′ of a);

FIG. 6A-C show schematic layouts for illustrating a manufacturing method of an integrated circuit in form of a capacitor array according to a sixth embodiment of the present invention, namely a) as plain view, b) as a cross-section along line A-A′ of a), and c) as a cross-section along line B-B′ of a);

FIG. 7A-D show schematic layouts for illustrating a manufacturing method of an integrated circuit in form of a capacitor array according to a seventh embodiment of the present invention, namely a) as plain view, b) as a cross-section along line A-A′ of a), and c) as a cross-section along line B-B′ of a);

FIG. 8A-C show schematic layouts for illustrating a manufacturing method of an integrated circuit in form of a capacitor array according to an eighth embodiment of the present invention, namely a) as plain view, b) as a cross-section along line A-A′ of a), and c) as a cross-section along line B-B′ of a); and

FIG. 9A-D show schematic layouts for illustrating a manufacturing method of an integrated circuit in form of a capacitor array according to a ninth embodiment of the present invention, namely a) as plain view, b) as a cross-section along line A-A′ of a), and c) as a cross-section along line B-B′ of a).

In the Figures, identical reference signs denote equivalent or functionally equivalent components.

### DESCRIPTION OF THE PREFERRED EMBODIMENTS

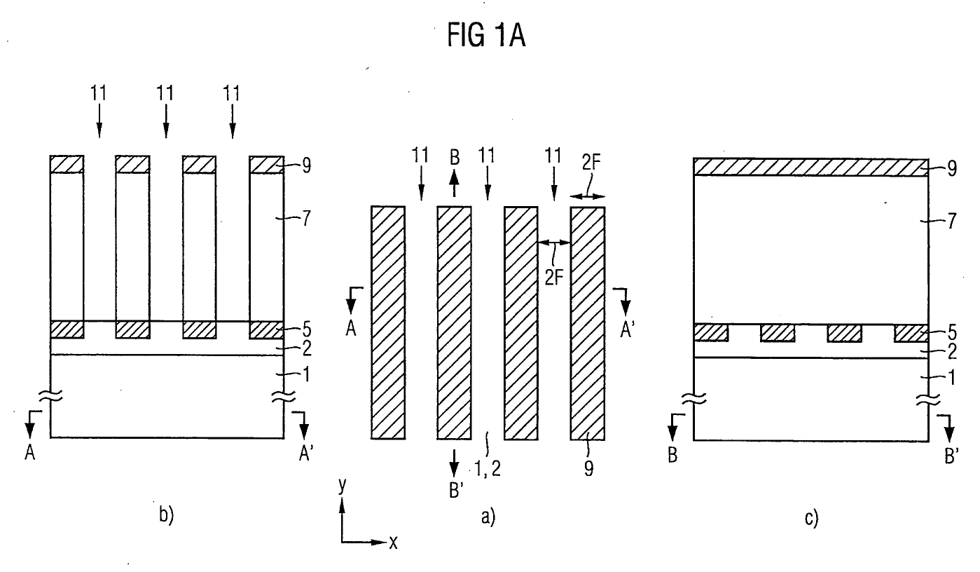

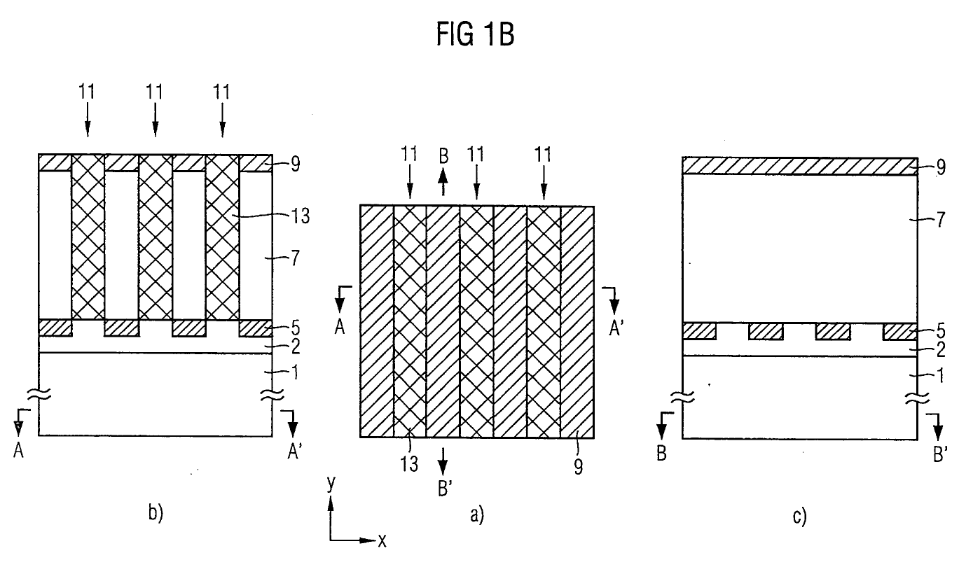

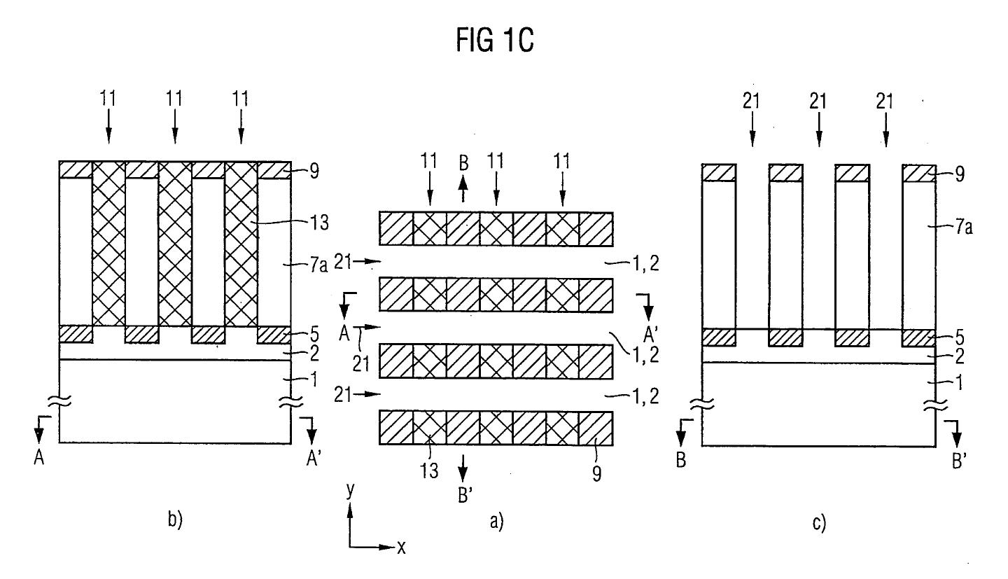

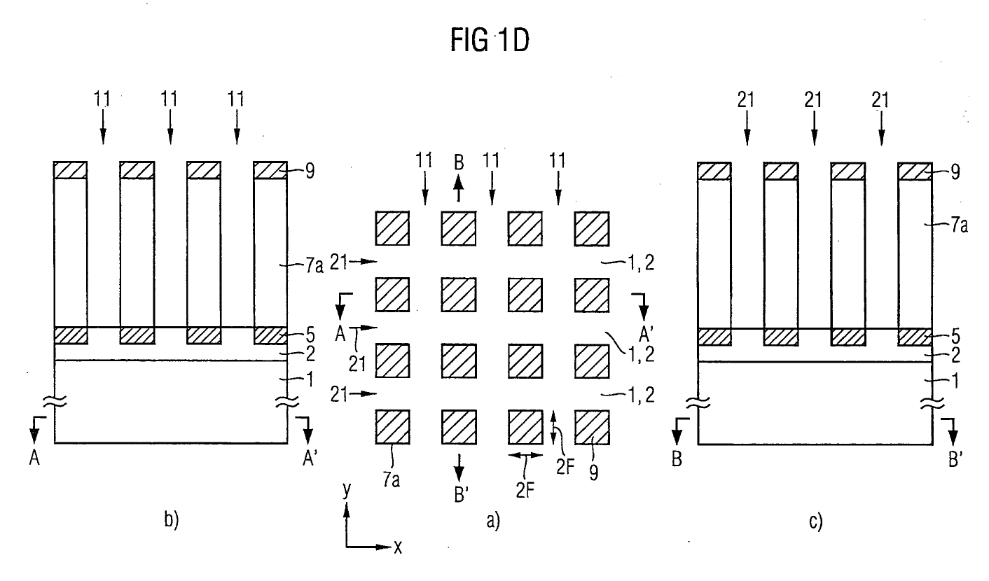

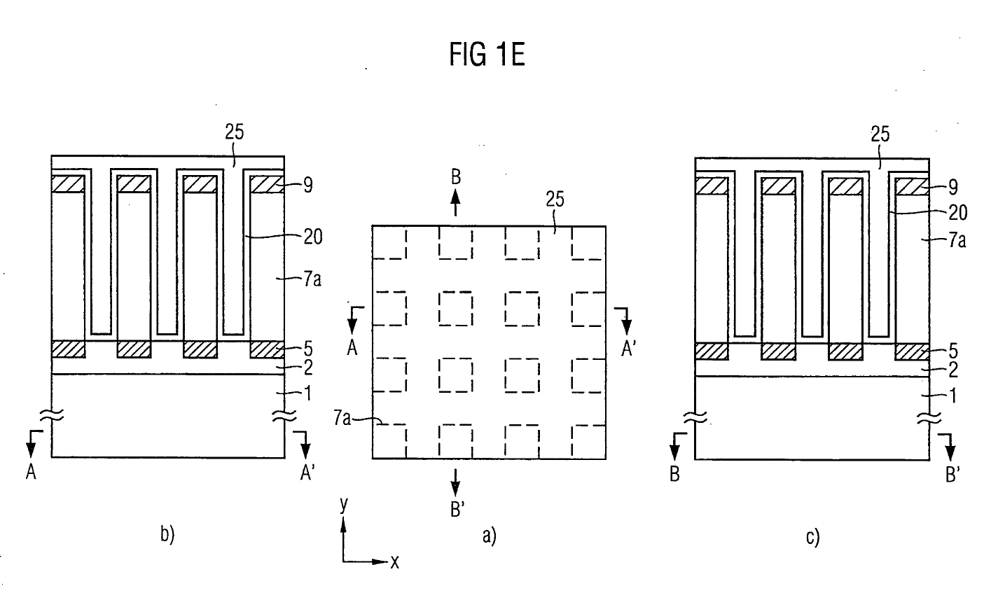

FIG. 1A-E show schematic layouts for illustrating a manufacturing method of an integrated circuit in form of a capacitor array according to a first embodiment of the present invention, namely a) as plain view, b) as a cross-section along line A-A′ of a), and c) as a cross-section along line B-B′ of a).

In FIG. 1A reference sign 1 denotes a semiconductor substrate, e.g. a silicon substrate, wherein a (not shown) integrated circuit is formed. An example for such an integrated circuit is a memory cell array comprising a matrix of memory cell transistors which can be driven by corresponding wordlines and bitlines.

Reference sign 2 denotes an insulating layer, e.g. an oxide layer, in which an array of capacitor electrode contacts 5 is arranged in rows along the x-direction and in columns along the y-direction. Each of said contacts 5 is connected to a respective memory cell transistor (not shown) by a corresponding wiring line (not shown). The contacts 5 are insulated from each other by being embedded in said insulating layer 2.

Although not limited thereto, in the examples shown here the contacts have a square form and occupy an area of 2F×2F=4F², where F is the critical dimension of the used patterning technology. The pitch between adjacent contacts 5 in x- and y-directions amounts to 2F. Thus, the surface of the contact array has a checkerboard form.

After having formed the contacts 5 embedded in said insulating layer 2, a conductive layer 7, e.g. a first polysilicon layer 7, is deposited over the entire lo structure. Thereafter, a protective layer 9, e.g. a silicon nitride layer 9, is deposited on top of said polysilicon layer 7.

Thereafter, a (not shown) stripe mask is formed on the protective nitride layer 9 having stripes of a width of 2F, which stripes cover the columns of contacts 5 running in y-direction. In a subsequent etch step, the protective nitride layer 9 and the conductive electrode layer in form of the first polysilicon layer 7 are etched in order to form first trenches 11 having a width of 2F. These first trenches 11 expose the insulating layer 2 between the columns of contacts 5 which remain covered by corresponding stripes of said conductive silicon layer 7 and protective nitride layer 9. Between the first trenches 11, there remain fins of said first conductive polysilicon layer 7 covered by said protective nitride layer 7. The hardmask is removed after the trench etch step. This leads to the process status shown in FIG. 1A.

As depicted in FIG. 1B, a SiGe infill 13 is provided in said first trenches 11 by depositing and polishing a SiGe layer. After the polishing step which stops on the protective nitride layer 9, the upper surface of the SiGe infill 13 and the protective nitride layer 9 is on the same level.

It should be mentioned that the infill 13 is not limited to SiGe, but can be any sacrificial material that can be selectively removed with respect to the conductive electrode layer in form of the first polysilicon layer 7 (see below).

In a subsequent process step which is shown in FIG. 1C, a second stripe mask is provided on the upper surface of the structure of FIG. 1B, said stripes of said second mask having a pitch of 2F and overlying the rows of contacts 5 running along the x-direction. Then, a second etch step is performed which removes the polysilicon of the conductive electrode layer in form of the first polysilicon layer 7 and the SiGe of the SiGe infill 13 between the rows of contacts running in x-direction and exposes the underlying insulating layer 2. Thus, second trenches 21 are formed between the rows of contacts 5 running in x-direction. After this second trench etch step, the final pillars 7a form of the first capacitor electrodes structured from the conductive polysilicon layer 7 are obtained, i.e. having dimensions of 2F×2F=4F².

As shown in FIG. 1D, the remaining SiGe infill 13 is selectively stripped in an etch step, leaving freely standing pillars 7a as first capacitor electrodes on said contacts 5.

Having regard to FIG. 1E, a capacitor dielectric layer 20 is deposited over the resulting structure of FIG. 1D, whereafter a second conductive layer 25, e.g. a second polysilicon layer 25, is deposited over the resulting structure so as to become a common second capacitor electrode.

After this process step, an array of capacitors has been formed over the substrate 1, each of said capacitors having an individual first capacitor electrodes in form of a pillar 7a connected to an associated contact 5, a capacitor dielectric layer 20, and a common second capacitor electrode 25.

Although explicitly mentioned below in the description of another embodiment, it should be already mentioned here that the protective nitride layer 9 could be removed before the steps of forming said dielectric layer 20 and said conductive layer 25 in form of said second polysilicon layer 25.

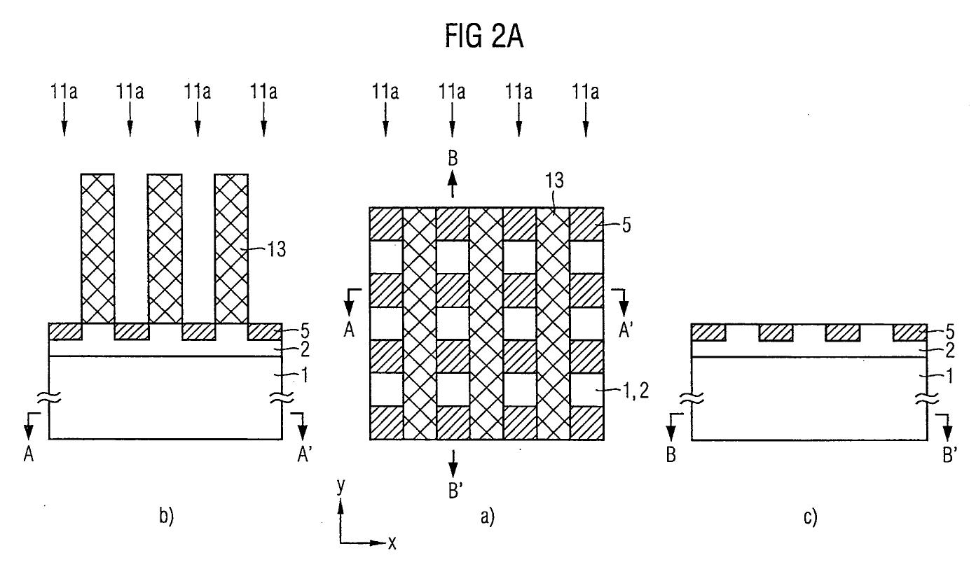

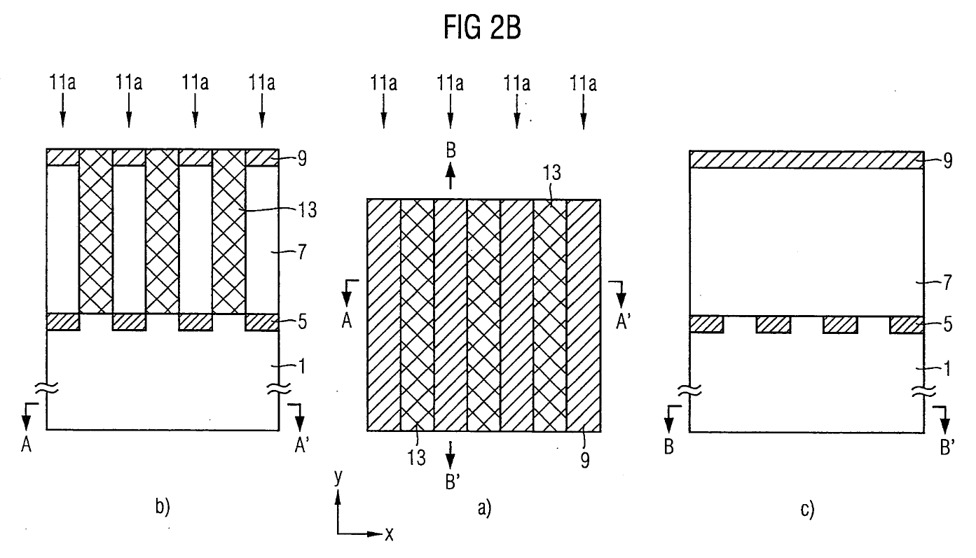

FIG. 2A,B show schematic layouts for illustrating a manufacturing method of an integrated circuit in form of a capacitor array according to a second embodiment of the present invention, namely a) as plain view, b) as a cross-section along line A-A′ of a), and c) as a cross-section along line B-B′ of a).

In the second embodiment, a selectively etchable sacrificial layer 13, f.e. a SiGe infill layer 13, is deposited over the array of contacts 5 embedded in the insulating layer 2. Then, a first stripe mask having stripes of a pitch of 2F are formed over the sacrificial SiGe infill layer 13, said stripes running along the insulating layer 2 stripes between the columns of contacts 5 running in y-direction.

Thereafter, a SiGe etch step is performed in order to form first trenches 11a which expose the columns of contacts 5 running along the x-direction. Thereafter, the first stripe mask is removed. This leads to the process status shown in FIG. 2A.

As may be obtained from FIG. 2B, the first conductive layer 7, e.g. a first polysilicon layer 7, is then deposited over the entire structure and etched back in said trenches 11a. Thereafter, the protective nitride layer 9 is deposited and polished back to the upper surface of the remaining fins of the sacrificial SiGe infill layer 13.

Here it should be mentioned that it is also possible to omit the protective nitride layer 9 and form the first conductive polysilicon layer 7 to the same level as said sacrificial SiGe infill layer 13.

The remaining process steps after the process status of FIG. 2B correspond to the process steps already explained above with respect to FIGS. 1C-1E.

Thus, the only difference between the first and second embodiment consists in the order in which the sacrificial SiGe layer 13 and the first conductive polysilicon layer 7 are formed.

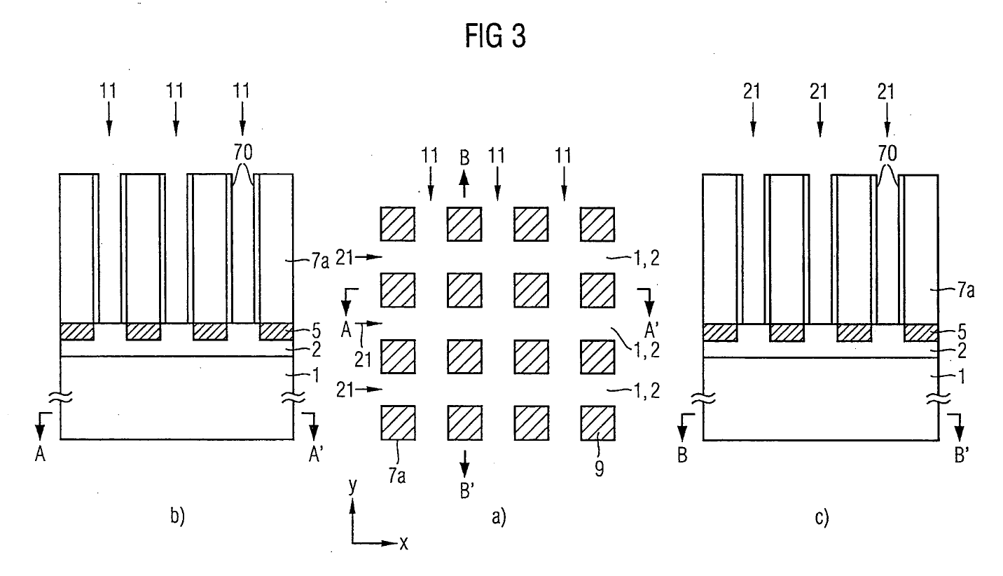

FIG. 3 show schematic layouts for illustrating a manufacturing method of an integrated circuit in form of a capacitor array according to a third embodiment of the present invention, namely a) as plain view, b) as a cross-section along line A-A′ of a), and c) as a cross-section along line B-B′ of a).

The third embodiment shown in FIG. 3 starts with the process status shown in FIG. 1D. Then, the protective nitride layer 9 is removed, and conductive spacers 70, e.g. made of metal or polysilicon, are formed on the sidewalls of the pillars 7a. These spacers 70 allow to enlarge the capacitor area of said first pillar-like capacitor electrodes.

A first possibility of forming the conductive spacers 70 includes depositing and anisotrophically etching a corresponding conductive material layer.

Another possibility would be a silicide process including the steps of depositing a titanium layer over said pillars 7a, tempering the structure to form TiSi on the sidewalls of said pillars 7a and finally removing the remaining titanium of the titanium layer by a corresponding selective etch step. Of course, other metal silicides different from TiSi may be formed analogously.

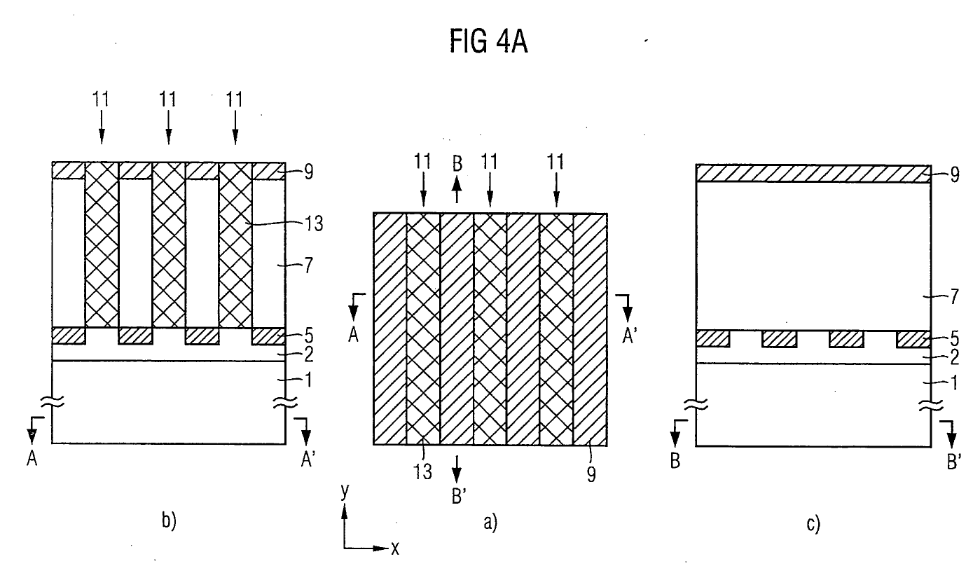

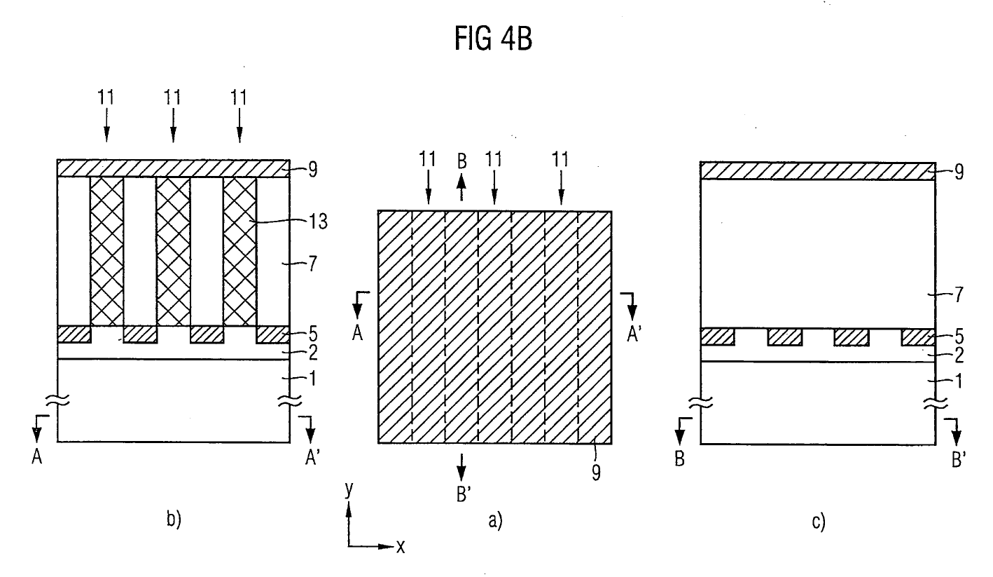

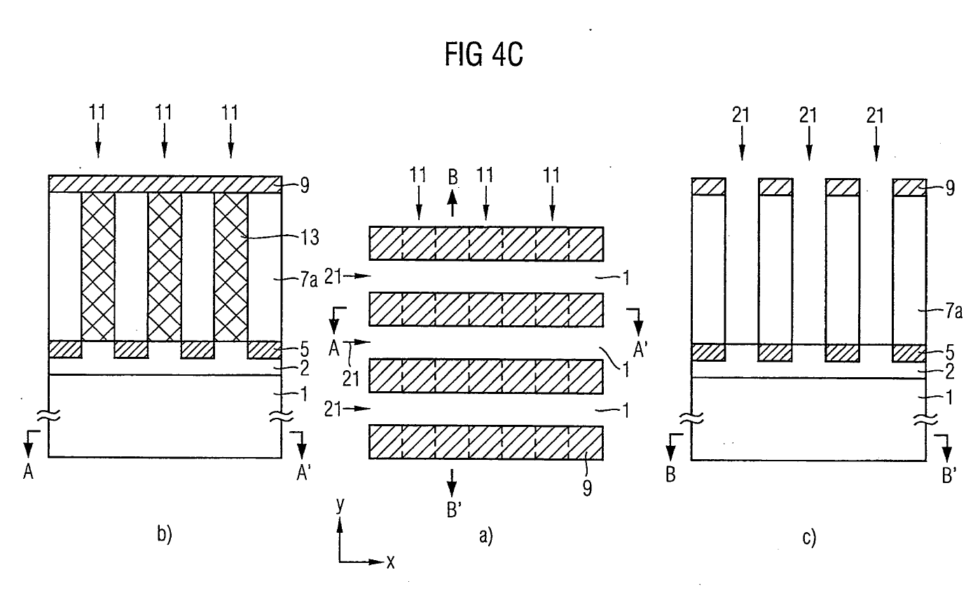

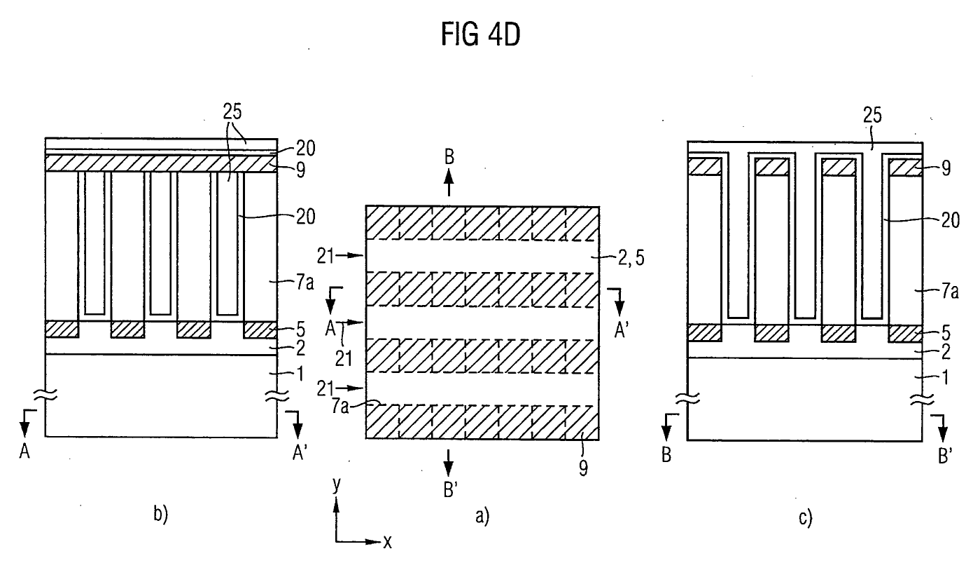

FIG. 4A-D show schematic layouts for illustrating a manufacturing method of an integrated circuit in form of a capacitor array according to a fourth embodiment of the present invention, namely a) as plain view, b) as a cross-section along line A-A′ of a), and c) as a cross-section along line B-B′ of a).

The fourth embodiment starts with the process step of FIG. 1 B which corresponds to FIG. 4A.

As shown in FIG. 4B, the sacrificial SiGe infill 13 is recessed from the upper surface to the depth of the protective nitride layer 9, and thereafter the gaps are filled with nitride in order to obtain a nitride layer 9 which fully covers the contact 5 array.

Here it should be mentioned that it is also possible to perform a CMP step and then deposit a planar nitride layer 9 or to only deposit a planar nitride layer 9 on the structure of FIG. 4A.

Further with respect to FIG. 4C, the second trenches 21 are formed between the rows of contacts 5 running along the x-direction as already explained with respect to FIG. 1C.

As depicted in FIG. 4D, the sacrificial SiGe infill 13 is stripped in a corresponding etch step, however, the protective nitride layer 9 is kept. By keeping the protective nitride layer 9 after having removed the sacrificial SiGe infill 13, an enhanced stability can be obtained along the rows of pillars 7a running in x-direction, because the pillars 7a are firmly connected to each other at their upper surfaces during said deep wet etch step for removing said sacrificial SiGe infill 13 and thereafter.

After removal of the sacrificial SiGe infill 13, the capacitor dielectric layer 20 and the second capacitor electrode layer 25, e.g. made of polysilicon, are formed over the entire structure which leads to the final status shown in FIG. 4D.

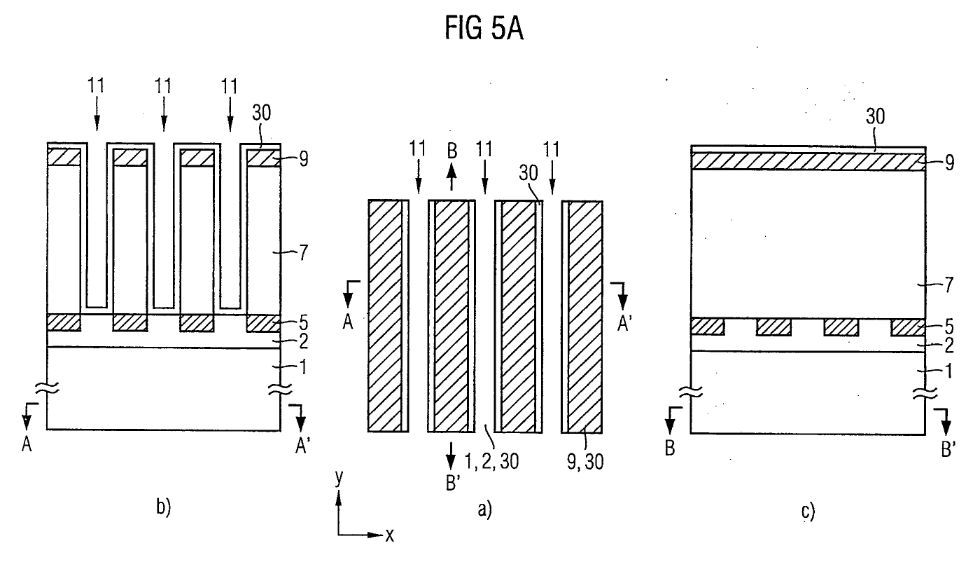

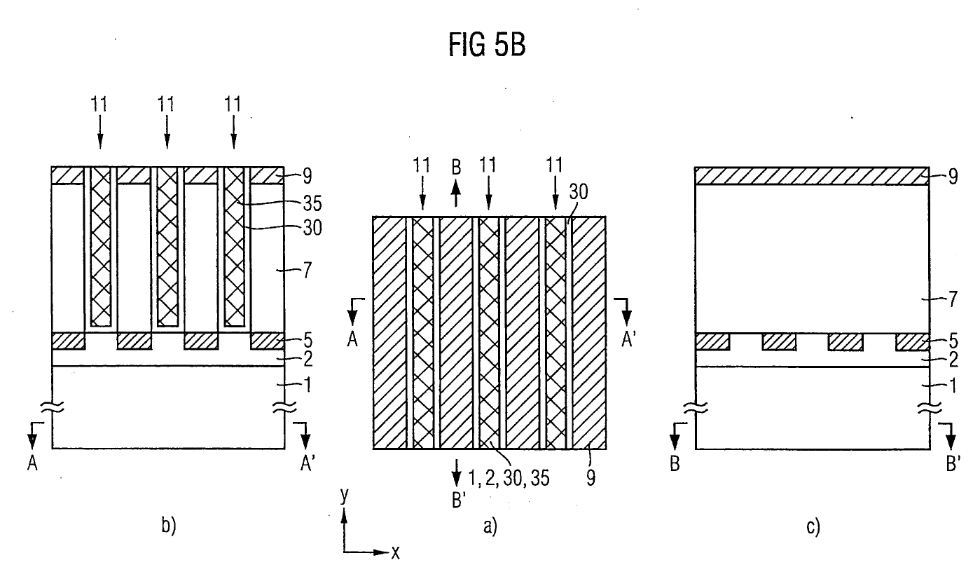

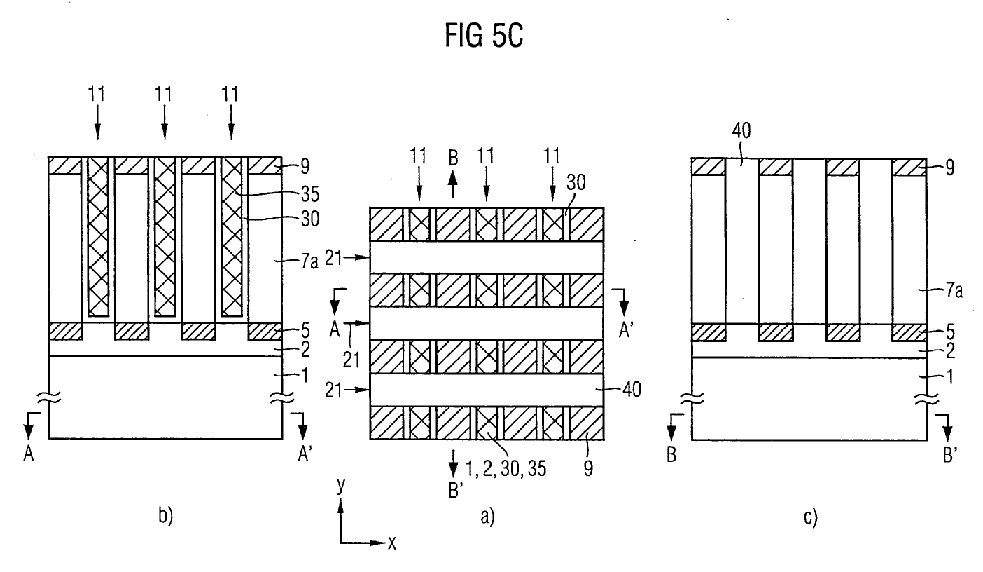

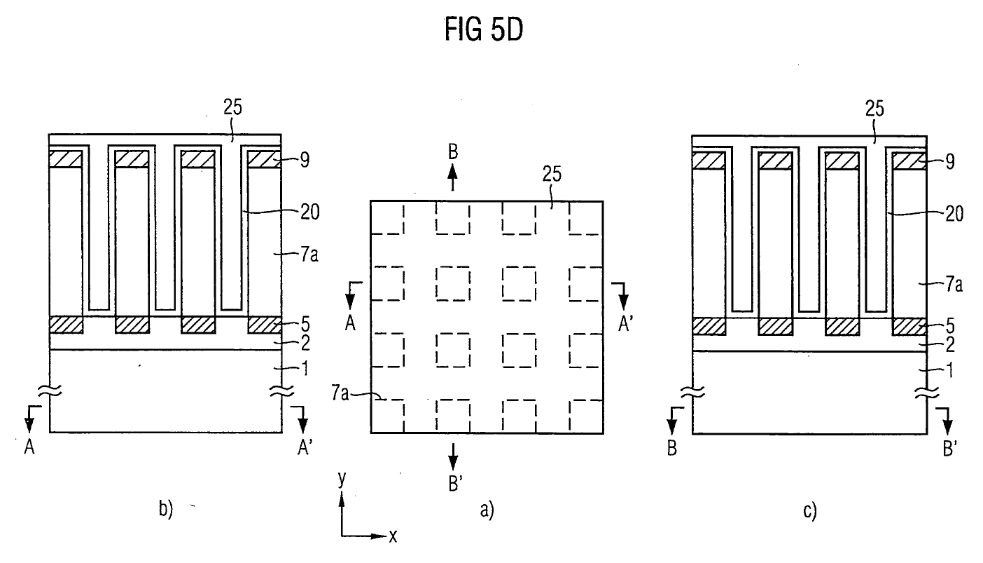

FIG. 5A-D show schematic layouts for illustrating a manufacturing method of an integrated circuit in form of a capacitor array according to a fifth embodiment of the present invention, namely a) as plain view, b) as a cross-section along line A-A′ of a), and c) as a cross-section along line B-B′ of a).

The fifth embodiment starts with the process status of FIG. 1A. Thereafter, an insulating liner layer 30, f.e. a nitride layer, is deposited over the entire array structure. This leads to the process status shown in FIG. 5A.

Subsequently, a selectively etchable sacrificial infill 35, f.e. a polysilicon infill 35, is formed in the first trenches 11 by depositing and polishing a polysilicon layer. After the polishing step, the upper surface of protective nitride layer 9 and the polysilicon infill 35 is at the same level, as may be obtained from FIG. 5B.

As depicted in FIG. 5C, the second trenches 21 are formed between the rows of contacts 5 running along the X-direction, as already explained above. Thus, the insulating layer 2 between the rows of contacts 5 is exposed. In a next process step, a sacrificial infill layer 40, e.g. an oxide infill layer 40, is deposited in the second trenches 21 and polished back to the upper surface of the protective nitride layer 9.

As depicted in FIG. 5D, the sacrificial polysilicon infill 35 is removed in a dry etch step, then the sacrificial oxide infill 40 is removed in a wet etch step, and then the insulating liner 30 is removed in another wet etch step. After removal of the insulating liner 30 the process status of FIG. 1D is obtained.

Finally, the capacitor dielectric layer 20 and the second capacitor electrode, e.g. made of the second conductive polysilicon layer 25, are formed.

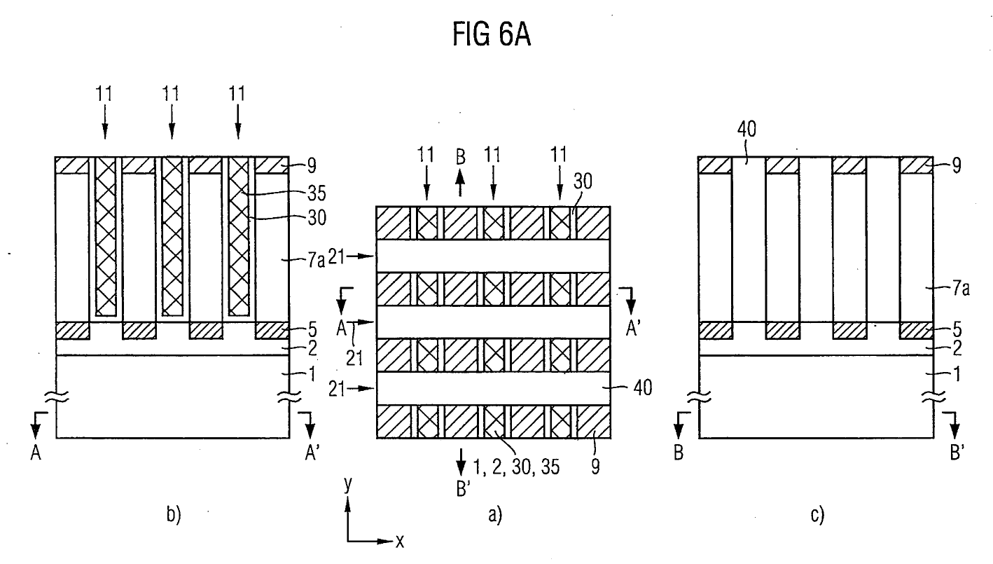

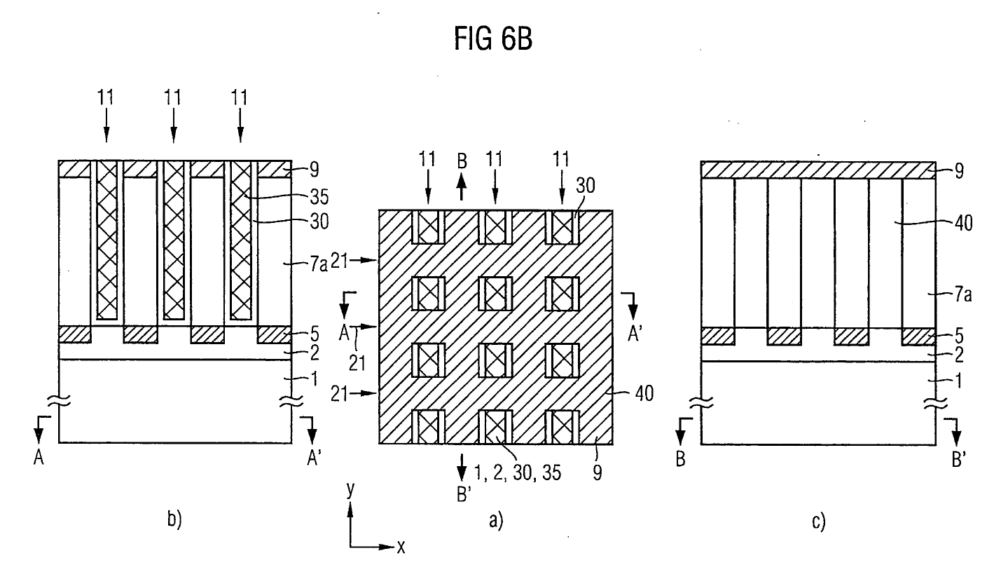

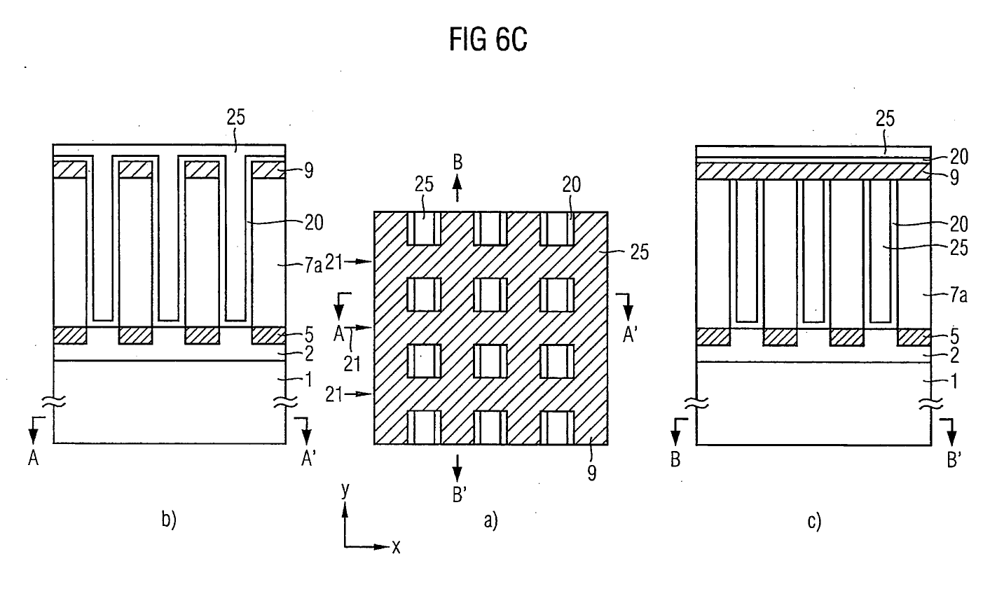

FIG. 6A-C show schematic layouts for illustrating a manufacturing method of an integrated circuit in form of a capacitor array according to a sixth embodiment of the present invention, namely a) as plain view, b) as a cross-section along line A-A′ of a), and c) as a cross-section along line B-B′ of a).

The sixth embodiment starts with the process status of FIG. 5C, which corresponds to FIG. 6A.

As shown in FIG. 6B, the sacrificial oxide infill 40 is selectively recessed to the depth of the upper surface of said pillars 7A. Then, nitride is deposited and polished back so as to form a mesh-like nitride layer 9 which surrounds the upper regions of the sacrificial polysilicon infill 35 and the liner 30. The mesh-like nitride layer 9 provides a stabilization of the upper surface of said pillars 7a which is efficient during the following process steps.

After completion of the mesh-like nitride layer 9, the sacrificial polysilicon infill 35 removed in a selective dry etch step. Thereafter, the remaining oxide infill 40 is removed in a corresponding selective wet etch step and finally the insulating liner 30 is removed in another selective wet etch step. After these three etch steps, only the stabilizing nitride layer 9 covers the upper surfaces of said pillars 7a and prevents any dislocation thereof.

As becomes apparent from FIG. 6C, the protective and stabilizing nitride layer 9 is kept, and then the capacitor dielectric layer 20 and the second capacitor electrode layer 25 are formed to complete the capacitor array of this embodiment.

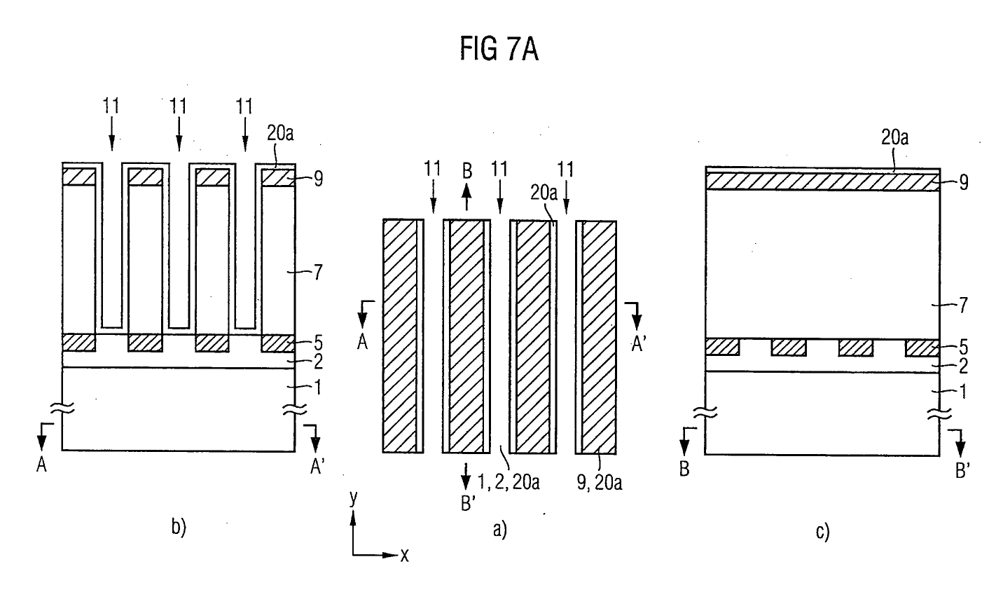

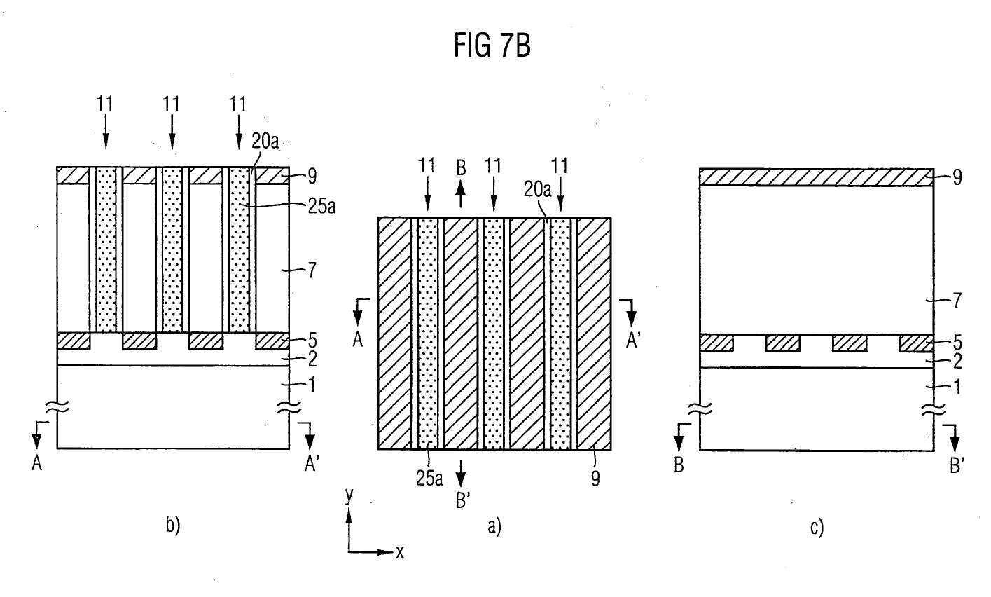

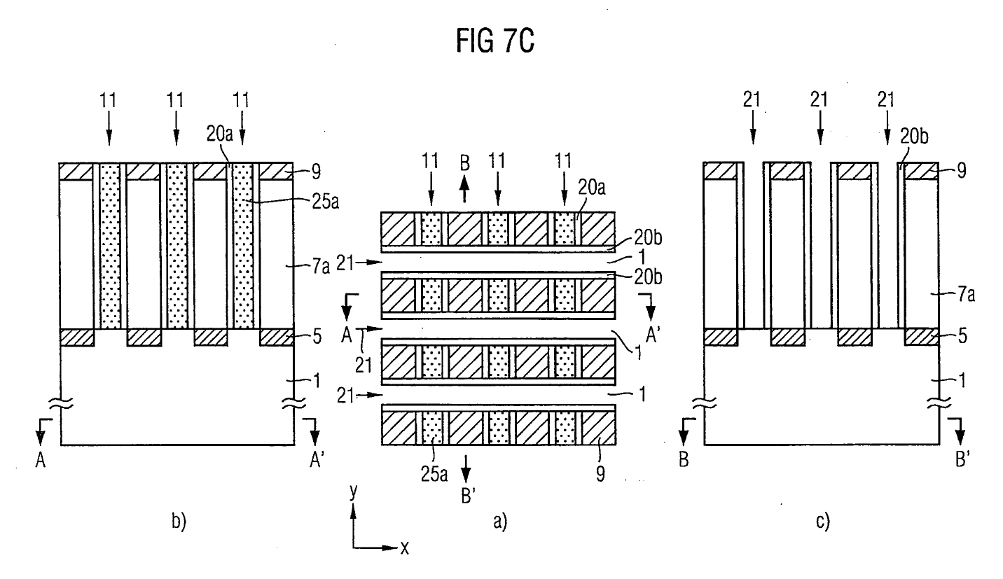

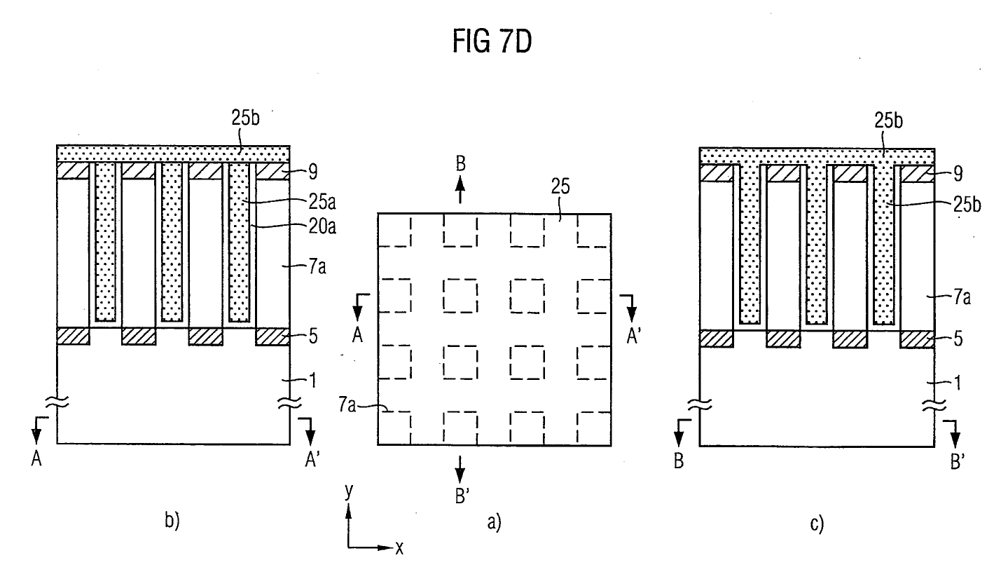

FIG. 7A-D show schematic layouts for illustrating a manufacturing method of an integrated circuit in form of a capacitor array according to a seventh embodiment of the present invention, namely a) as plain view, b) as a cross-section along line A-A′ of a), and c) as a cross-section along line B-B′ of a).

The seventh embodiment also starts with the process status shown in FIG. 1A. In this embodiment, a first part 20a of the capacitor dielectric layer is deposited over the structure of FIG. 1A, which leads to the process status shown in FIG. 7A.

Thereafter, a first part 25a of the second capacitor electrode is formed as polysilicon infill in the first trenches 11 polished back to the upper surface of the nitride layer 9. This leads to the process status shown in FIG. 7B.

According to FIG. 7C, the second trenches 21 are formed between the rows of contacts 5 running along the x-direction, and thereafter a second part 20b of the capacitor dielectric layer is deposited over the entire structure and polished back to the upper surface of the protective nitride layer 9.

Alternatively, said second part 20b of said capacitor dielectric layer could be selectively formed in a thermal oxidation process only on the exposed side-walls of said pillars 7.

Finally, as shown in FIG. 7D, the second part 25b of the second conductive capacitor electrode is formed, e.g. in a polysilicon deposition step over the entire structure.

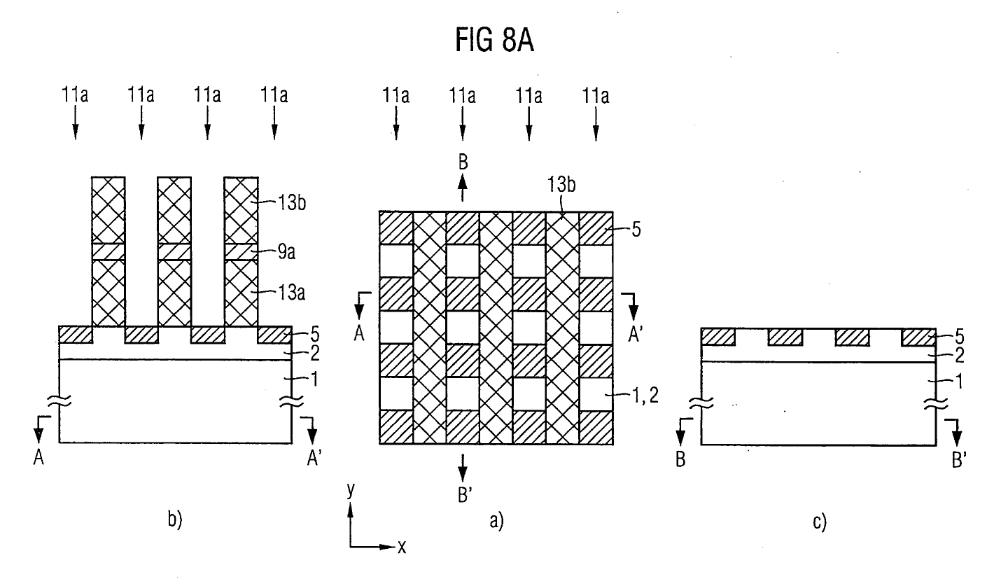

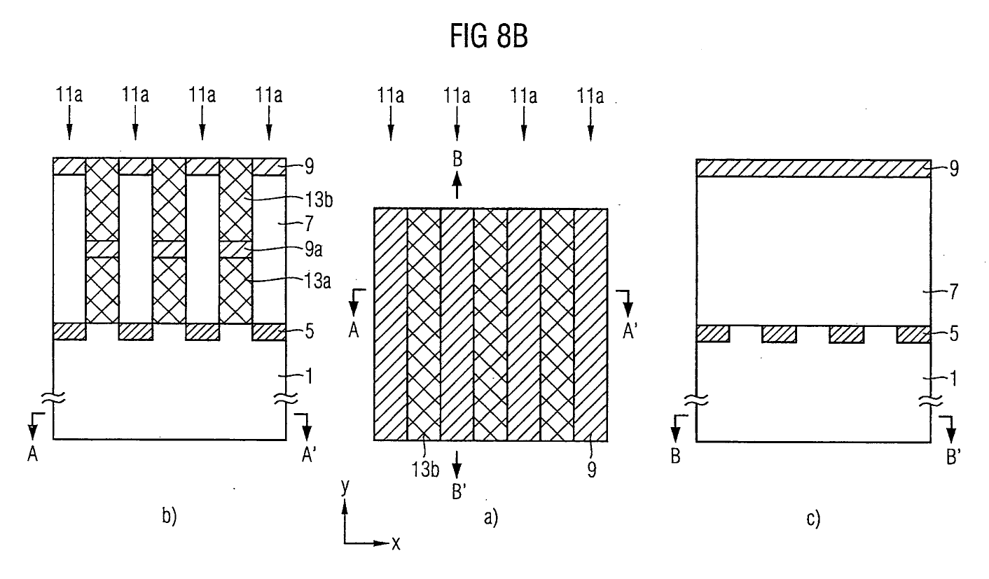

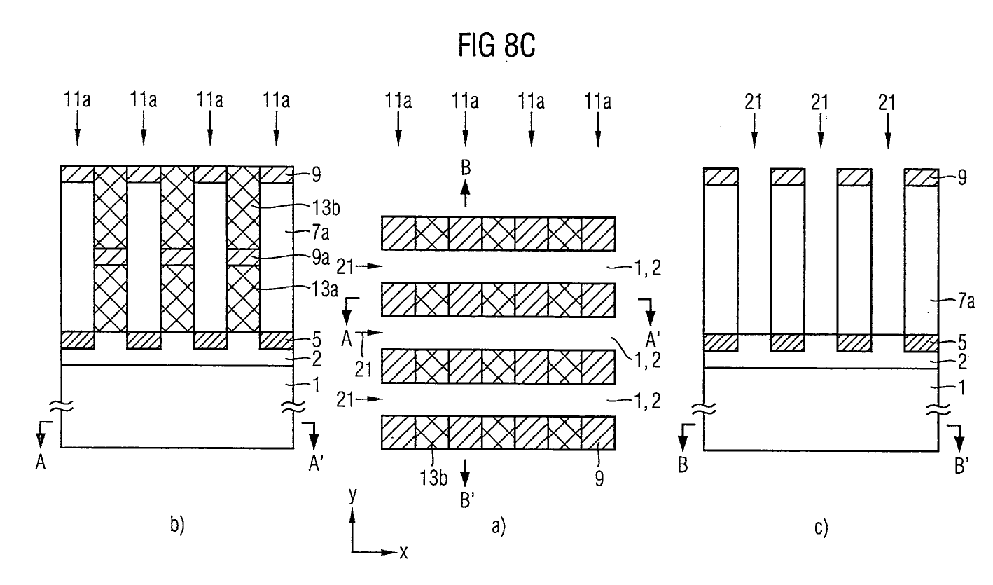

FIG. 8A-C show schematic layouts for illustrating a manufacturing method of an integrated circuit in form of a capacitor array according to an eighth embodiment of the present invention, namely a) as plain view, b) as a cross-section along line A-A′ of a), and c) as a cross-section along line B-B′ of a).

The eighth embodiment is very similar to the second embodiment described above with respect to FIGS. 2A, B.

As may be obtained from FIG. 8A, the only difference consists in the fact that the sacrificial SiGe infill layer 13 is deposited as sub-layers 13a, 13b, having an intermediate stabilizing layer, f.e. a silicon nitride layer 9a, for stabilization of the pillars 7a during a deep etch process.

The process status shown in FIG. 8B corresponds to the process status shown in FIG. 2B.

As shown in FIG. 8C, the second trenches 21 between the rows of contacts 5 running in x-direction are etched in a subsequent etch step. Then, the two sacrificial SiGe sublayers 13a, 13b are removed in a corresponding etch step leaving the stabilizing nitride layer 9A between adjacent pillars 7A. In analogy to the sixth embodiment explained above, this prevents dislocation of said pillars 7a during said deep infill etch step.

Finally, the first and second nitride layers 9, 9a are kept, and the capacitor dielectric layer 20 and the second capacitor electrode layer 25 are formed over the structure, which leads to the final process state.

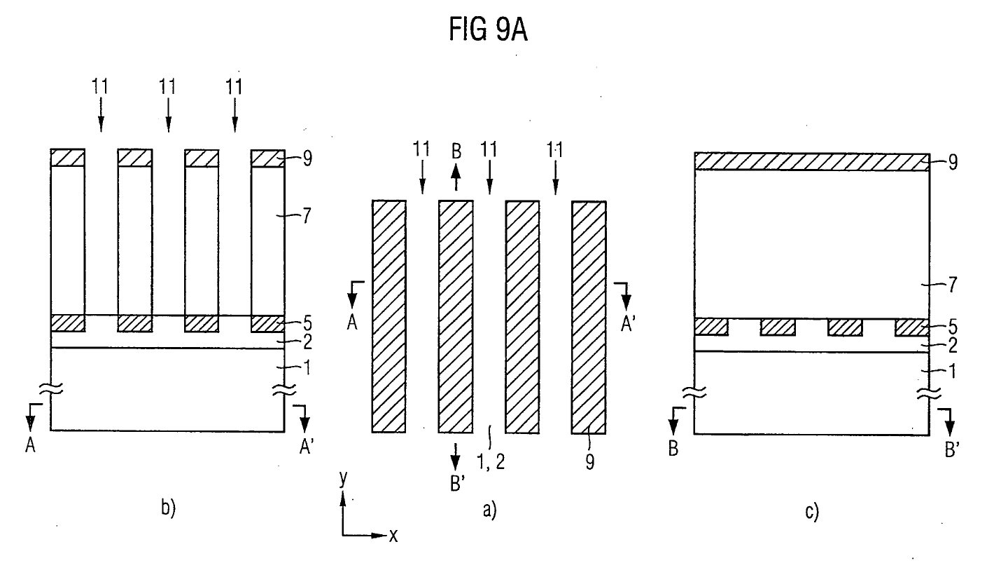

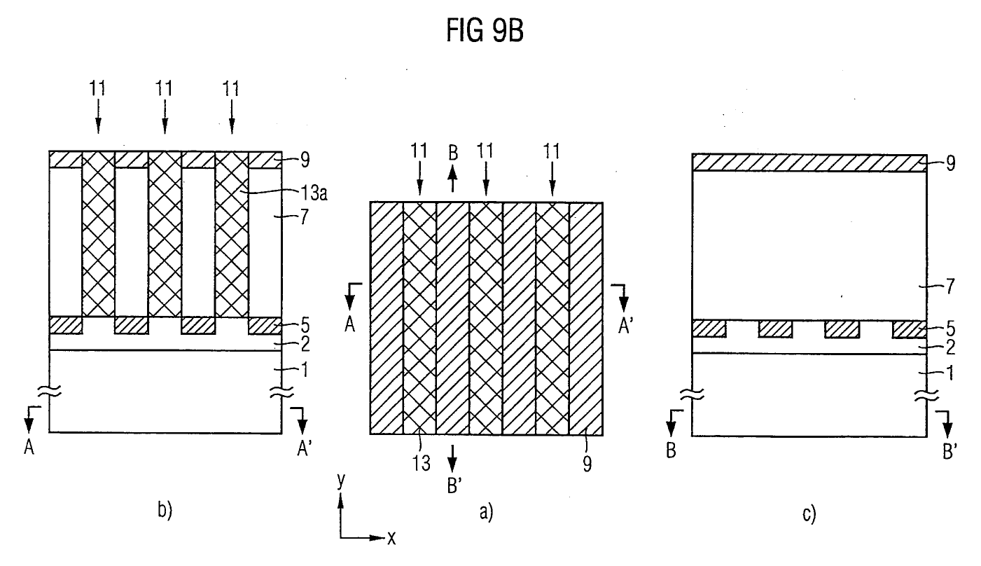

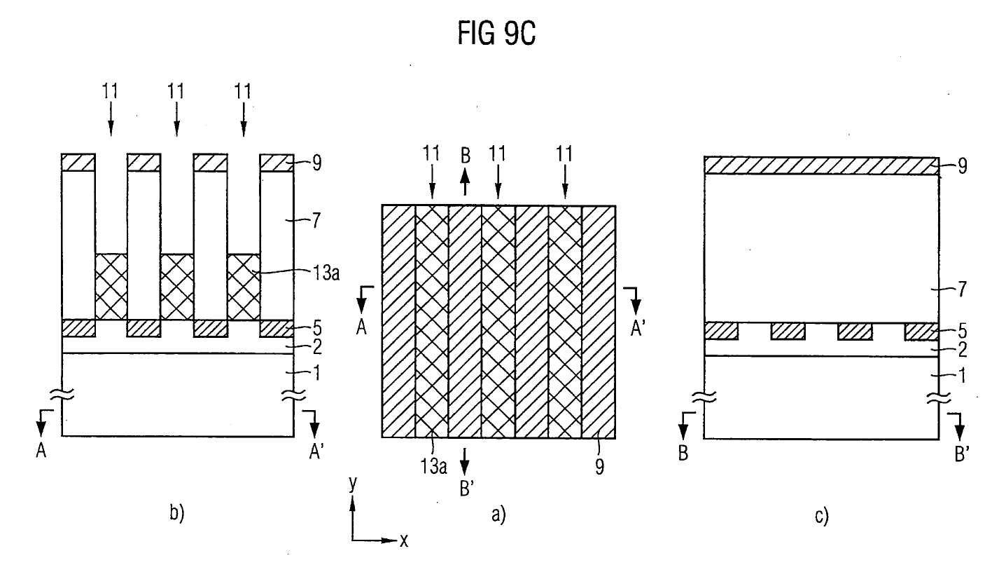

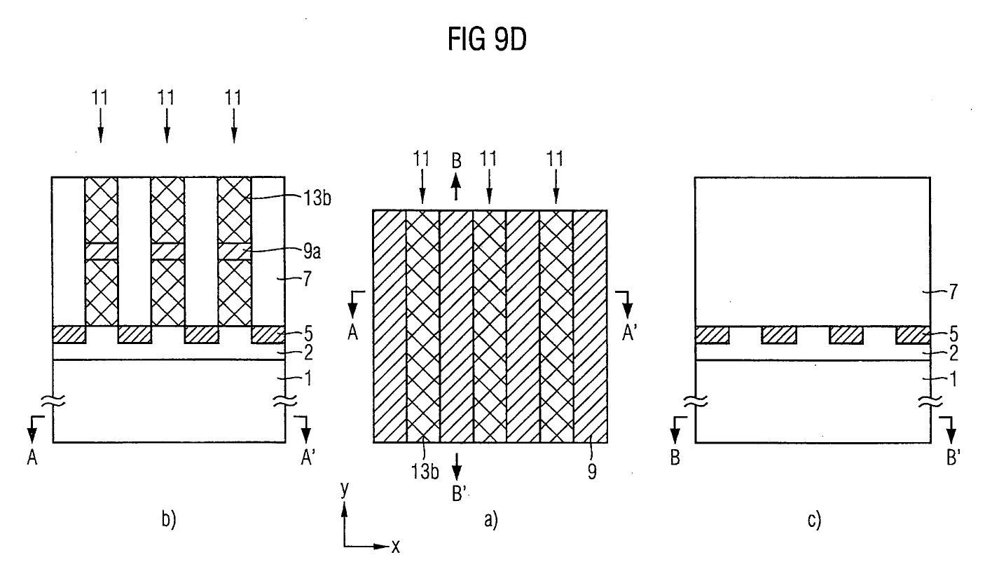

FIG. 9A-D show schematic layouts for illustrating a manufacturing method of an integrated circuit in form of a capacitor array according to a ninth embodiment of the present invention, namely a) as plain view, b) as a cross-section along line A-A′ of a), and c) as a cross-section along line B-B′ of a).

The ninth embodiment also starts with the process status shown in FIG. 1A corresponding to FIG. 9A.

Thereafter, a first sublayer 13a of said sacrificial SiGe infill is deposited as shown in FIG. 9B and then etched back to about 50% of the height of the first conductive polysilicon layer 7, as shown in FIG. 9C.

Then, an intermediate stabilizing layer 9a, e.g. a silicon nitride layer 9a, is deposited and etched back, and finally the second sublayer 13b of said sacrificial SiGe infill layer is deposited and polished back in the first trenches to have an upper surface which is equal to the upper surface of the first conductive polysilicon layer 7, as shown in FIG. 9D.

The remaining process steps are the same as already explained above with respect to the eight embodiments, namely etching the second trenches 21, removing the sublayers 13a, 13b, keeping said stabilizing silicon nitride layer 9a, and forming said capacitor dielectric layer 20 and said second capacitor electrode layer 25.

According to the exemplary embodiments described above, crossed stripes of masks are transferred into the first capacitor electrode material or into the fill material and into the first capacitor electrode material in order to facilitate the formation of semiconductor material pillars in comparison to a hole mask etch.

Although the present invention has been described with reference to preferred embodiments, it is not limited thereto, but can be modified in various manners which are obvious for a person skilled in the art. Thus, it is intended that the present invention is only limited by the scope of the claims attached herewith.

In should be mentioned, that the aspect explained with respect to the third embodiment shown in FIG. 3, namely enhancing the capacitor area by providing a conductive spacer, may of course be optionally applied for all of the embodiments.

The form of pillars does not have to be squares, but can be any form having four sidewalls, e.g. rhombic, parallelepiped.

Also, the present invention is not limited to the material combinations referred to in the above embodiments. Moreover, the invention is applicable for any kind of integrated circuity such as memories as DRAM, SRAM, ROM, NVRAM etc., and also for any other kind of integrated circuit devices that use pillar elements.

What is claimed is:

1. A method of manufacturing integrated circuit including a plurality of pillars, comprising the steps of:
forming a plurality of first trenches in a first layer comprising a first material, thereby leaving a plurality of fins of the first material between said trenches;
forming an infill comprising a second material in said first trenches;
forming a plurality of second trenches in said first layer and said infill, the second trenches having sidewalls, wherein first portions of said sidewalls expose the first material, and second portions of said sidewalls expose the second material; and
removing either the first or the second material selectively to the respective other material, thereby leaving said pillars of the remaining material.

2. The method of claim 1, wherein the step of removing one of the materials is an isotropic etch process.

3. The method of claim 1, wherein the step of removing one of the materials is a wet etch process.

4. The method of claim 1, wherein the plurality of first trenches runs essentially parallel to each other into a first direction, and wherein the plurality of second trenches runs essentially parallel to each other into a second direction.

5. The method of claim 4, wherein the first and second direction are perpendicular to each other.

6. The method of claim 1, further comprising the step of forming an liner of a third material in said first trenches before the step of forming an infill.

7. The method of claim 1, wherein said liner is made of an insulating etch stop material.

8. The method of claim 7, wherein said third material comprise one of the group of silicon nitride, silicon oxinitride, silicon oxide, and carbon.

9. The method of claim 1, wherein the second material is a sacrificial material comprising one of the group of amorphous silicon, polycrystalline silicon, silicon oxide, silicon nitride, silicon oxinitride, carbon, tungsten, titanium, titanium nitride.

10. The method of claim 1, wherein the first material is a sacrificial material comprising one of the group of amorphous silicon, polycrystalline silicon, silicon oxide, silicon nitride, silicon oxinitride, carbon, tungsten, titanium, titanium nitride.

11. The method of claim 1, wherein the first layer comprises a stabilization layer of a fourth material, and the step of selectively removing one of the first and second material comprises removing said first material selectively to said second and said fourth material.

12. The method of claim 11, wherein said fourth material comprise one of the group of silicon nitride, silicon oxinitride, silicon oxide, and carbon.

13. The method of claim 1, further comprising the following steps of depositing a dielectric layer onto said pillars; and depositing a conductive layer onto the dielectric layer.

14. The method of claim 13, wherein the pillars form a first electrode of a capacitive element, and the conductive layer forms a second electrode of said capacitive element, said electrodes being insulated from each other by said dielectric layer.

15. The method of claim 14, wherein the capacitive element is a storage element of a memory element.

16. The method of claim 13, wherein a conductive spacer is formed on the sidewalls of said pillars before the step of depositing a dielectric layer.

17. A method of forming an integrated circuit including a plurality of pillars made of a first material, comprising the steps of:
forming a first layer of said first material on a substrate;
forming a second layer of a second material on said first layer;
forming a plurality of first trenches in said first and second layer;
forming an first infill comprising a third material in said first trenches;
forming a plurality of second trenches in said filled first layer, said second trenches crossing said first trenches;
forming a second infill of a fourth material in said second trenches;
forming a recess of the second infill to the depth of the second layer;
filling the recess with the second material thereby obtaining a mesh-like second layer on said first layer;
selectively removing the first and second infill; and
thereafter selectively removing said second layer thereby obtaining said plurality of pillars.

18. The method of claim 17, wherein said first infill comprises a non-conductive liner material and a conductive fill material.

19. The method of claim 17, wherein said pillars are arranged on an array of contacts formed on a substrate.

20. An intermediate integrated circuit structure for forming a plurality of pillars, comprising:
a plurality of fins running into a first direction and extending vertically from a substrate surface, the plurality of fins comprising a plurality of portions of a first material and at least one portion of a second material, wherein the portions of the first and second material are arranged alternatingly along the first direction.

21. The intermediate integrated circuit structure of claim 20, wherein a layer of a third material is disposed between the plurality of portions of the first and the second material.

22. The intermediate integrated circuit structure of claim 20, wherein the extension of one of the portions of the first material into the first direction is equal to the extension of one of the portions of the second material into the first direction.

23. The intermediate structure of claim 20, wherein the first material is a sacrificial material comprising one of the group of amorphous silicon, polycrystalline silicon, silicon oxide, silicon nitride, silicon oxinitride, carbon, tungsten, titanium, titanium nitride.

24. The intermediate structure of claim 20, wherein said third material is a stabilizing material comprising one of the group of silicon nitride, silicon oxinitride, silicon oxide, and carbon.

25. An integrated circuit including a plurality of pillars, wherein the plurality of pillars is formed from an intermediate structure of claim 20.

26. The integrated circuit of claim 25, wherein the pillars form a first electrode of a respective capacitive element.

27. The integrated circuit of claim 26, wherein the capacitive element is a storage element of a memory element.

28. An integrated circuit including a plurality of conductive pillars, wherein the plurality of conductive pillars is arranged in rows running into a first direction and columns running into a second direction, wherein adjacent pillars of the same row are interconnected by a connecting element comprising a dielectric material.

29. The integrated circuit of claim 28, wherein said connecting elements are only interconnecting adjacent pillars of the same row.

30. The integrated circuit of claim 28, wherein said connecting elements are interconnecting adjacent pillars of the same row and the same column.

31. The integrated circuit of claim 28, wherein said connecting elements are located on the upper surface of said pillars.

32. The integrated circuit of claim 28, wherein said connecting elements are located between said pillars.
